(19) United States
(12) Patent Application Publication
(10) Pub. No.: US 2003/0030455 A1
(43) Pub. Date: Feb. 13, 2003

(54) Test probe having a sheet body

(75) Inventors: Michinobu Tanioka, Tokyo (JP); Takahiro Kimura, Tokyo (JP)

Correspondence Address: Paul-J. Esatto, Jr., Scully, Scott, Murphy & Presser, 400 Garden City Plaza, Garden City, NY, 11530, US

(73) Assignee: NEC Corporation, Tokyo (JP)

(21) Appl. No.: 10/195,878

(22) Filed: Jul. 15, 2002

Related U.S. Application Data
(62) Division of application No. 09/612,127, filed on Jul. 7, 2000, now abandoned.

(30) Foreign Application Priority Data
Jul. 8, 1999 (JP) 11-193961

(51) Int. Cl. G01R 31/02

(52) U.S. Cl. 324/754

(57) ABSTRACT

A test probe has a sheet body including an insulating sheet and a wiring sheet formed on the bottom surface of the insulating sheet. The insulating sheet mounts on the top surface a plurality of top electrodes arranged with a small pitch, whereas the wiring sheet mounts on the bottom surface a plurality of bottom electrodes connected to the top electrodes through via-holes in the insulating sheet and interconnect layers in the wiring sheet. A smaller pitch of the top electrodes is suited for a bare chip LSI, whereas a larger pitch of the bottom electrodes reduces the cost for a test board.

### BACKGROUND OF THE INVENTION

(a) Field of the Invention

The present invention relates to a test probe having a sheet body and, more particularly, to a test probe suited for testing a bare chip of a LSI having a high-density electrode array.

(b) Description of the Related Art

An electric test for a bare chip LSI is generally conducted by a test system having a test board for mounting the bare chip and a test instrument for testing the bare chip through the test board. The test board includes an array of electrodes in number corresponding to the number of the electrodes on the bare chip. A test probe is generally used for electrically connecting the electrodes on the bare chip with the respective electrodes of the test board.

A conventional test probe is known which includes a first probe plate used for an electrode of the bare chip, a second probe plate used for an electrode of the test board, and a spring for coupling the first probe plate and the second probe plate. This type of the test probe is provided for each of the electrodes of the bare chip, and the spring is provided for the purpose of obtaining a suitable electric contact between the electrodes of the bare chip and the test board.

The conventional test probe as described above has a disadvantage in that a fixing member used for fixing the plurality of the test probes has a complicated structure and thus is expensive. In addition, there is a limitation for a smaller pitch for the arrangement of the test probes, and accordingly, it is not practical for the small-pitch electrodes of the current bare chip LSI.

Another test probe is also known which includes a probe body and a plurality of probe pins (or test pins) mounted on the probe body and each used for connecting an electrode of the bare chip and a corresponding electrode of the test board. As for the another test probe, it is also expensive to fabricate the test probe from the probe body and a plurality of the probe pins. In addition, it is difficult to adapt the arrangement of the test pins to the smaller pitch of the electrodes in the bare chip LSI.

### SUMMARY OF THE INVENTION

In view of the above, it is an object of the present invention to provide a test probe which is suited for a smaller pitch of electrodes in the bare chip.

It is another object of the present invention to provide a method for fabricating such a test probe.

The present invention provides a test probe including a sheet body having a top surface and a bottom surface, a plurality of first electrodes formed on the top surface, a plurality of second electrodes formed on the bottom surface and each corresponding to one of the first electrodes, and a plurality interconnects each formed inside the sheet body for connecting one of the first electrodes to a corresponding one of the second electrodes.

The present invention also provides a method for fabricating a test probe including the steps of forming a plurality of first electrodes on a top surface of an insulating sheet, forming a wiring sheet on a bottom surface of the insulating sheet, the wiring sheet having therein a plurality of interconnects each corresponding to one of the first electrodes, forming a via-hole in the insulating sheet for connecting one the first electrodes and a corresponding one of the interconnects, and forming on the wiring sheet a plurality of second electrodes each connected to a corresponding one of the interconnects.

In accordance with the present invention, the sheet body of the test probe is suited for inserting the test probe between the bare chip LSI and the test board. The sheet body can be deformed by an external force to thereby adapt to the shape of the test board and the bare chip.

In addition, the first electrodes may be arranged with a smaller pitch compared to the second electrodes by using a technique for fabricating a semiconductor device, thereby adapting the arrangement of the first electrodes to the arrangement of the electrode pads of a bare chip LSI having a smaller-pitch electrode array.

The above and other objects, features and advantages of the present invention will be more apparent from the following description, referring to the accompanying drawings.

### BRIEF DESCRIPTION OF THE DRAWINGS

FIG. 1 is a top plan view of a test probe according to a first embodiment of the present invention.

FIG. 2 is a side view as viewed along line II-II in FIG. 1.

FIG. 3 is a sectional view taken along line III-III in FIG. 1.

FIG. 4 is a sectional view of the test probe of FIG. 1 connected to a test board.

FIGS. 5A to 5Q are sectional views consecutively showing fabrication steps of a process for fabricating the test probe of FIG. 1.

FIGS. 6A to 6K are sectional views consecutively showing fabrication steps of a process for forming the projection in the test probe of FIG. 1.

FIG. 7 is a sectional view of a test probe according to a second embodiment of the present invention.

FIG. 8 is a sectional view of a test probe according to a second embodiment of the present invention.

### PREFERRED EMBODIMENT OF THE INVENTION

Now, the present invention is more specifically described with reference to accompanying drawings, wherein similar constituent elements are designated by related reference numerals.

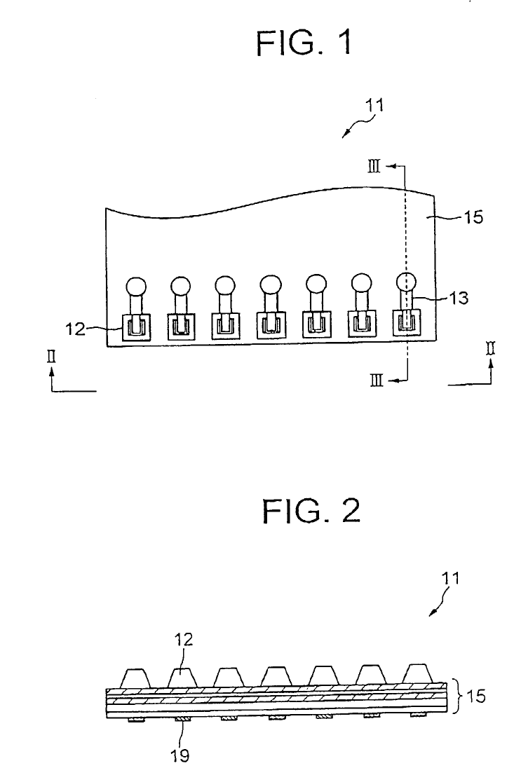

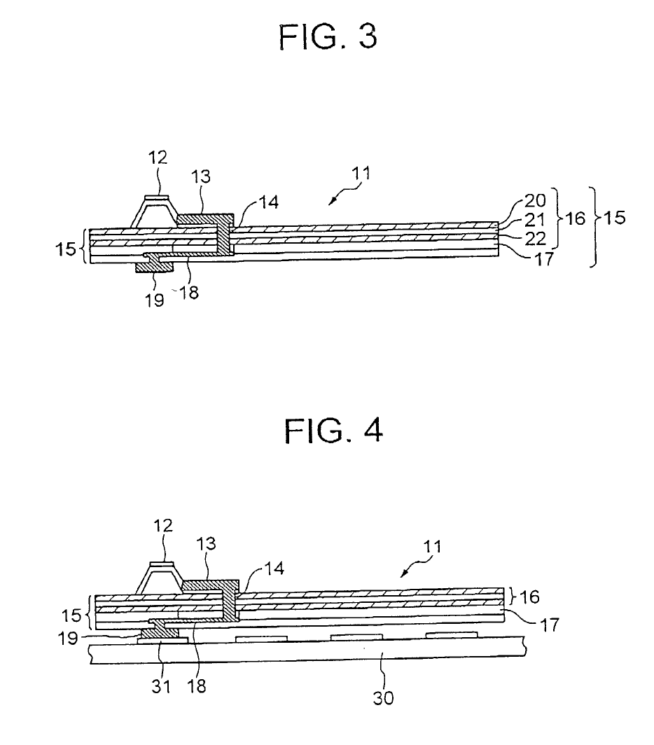

Referring to FIGS. 1 and 2, a test probe, generally designated by numeral 11, according to an embodiment of the present invention includes a sheet body 15 having a multilayered structure, a plurality of projecting electrodes 12 arrayed on the top surface of the sheet body 15 in the vicinity of the periphery thereof, an interconnect 13 disposed on the top surface of the sheet body 15 for each of the projecting electrodes 12, and a plurality of bottom electrodes 19 arrayed on the bottom surface of the sheet body 15 in the vicinity of the periphery of thereof. The bottom electrodes 19 are connected to respective projecting electrodes 12 via internal interconnects, via-holes and the interconnects 13.

The number and the pitch of the projecting electrodes 12 correspond to the number and the pitch of the electrodes of the bare chip LSI not shown. On the other hand, the number and the pitch of the bottom electrodes correspond to the number and the pitch of the electrodes of the test board not shown.

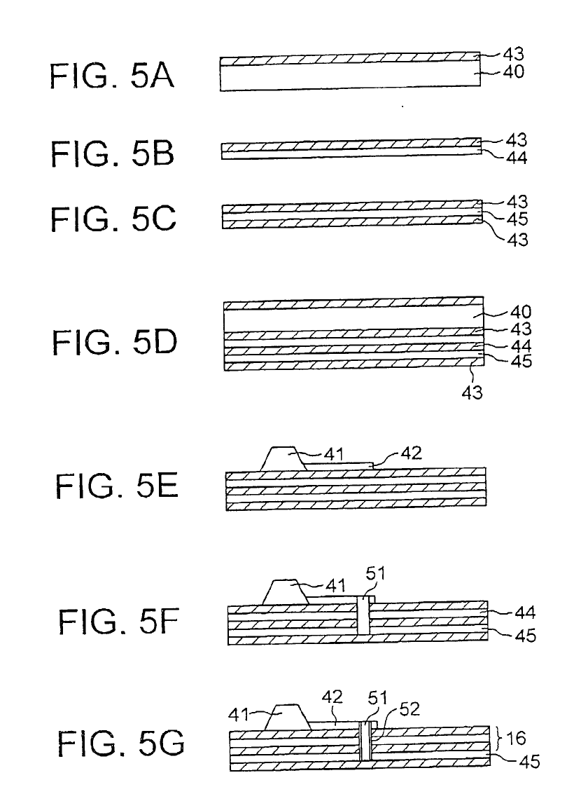

Referring to FIG. 3, the sheet body 15 includes an insulating sheet 16 including a silicon (Si) layer 21 and a pair of silicon oxide (SiO₂) layers 20 and 22 disposed on both sides of the silicon layer 21, and a multilayer wiring sheet 17 disposed on the bottom surface of the insulating sheet 16. The wiring sheet 17 includes a resin body made of photoresist resin, and a plurality of interconnect pattern layers 18 formed inside the resin body. The bottom electrodes 19 are disposed on the bottom surface of the wiring sheet 17, which is directed to a test board (not shown in the figure) during a test operation.

A via-hole 14 penetrates the insulating sheet 16 for connecting the interconnect 13 formed on the top surface of the insulating sheet 16 and a corresponding bottom electrode 19 formed on the bottom surface of the wiring sheet 17. The via-hole 14 has an overcoat thereon for electrically insulating from the silicon layer 21 of the insulating sheet 16. The interconnect pattern layers 18 adjust the difference between the pitch of the electrode pads of the test board and the pitch of the electrode pads of the bare chip, the latter being generally smaller compared to the former. The number of the interconnect pattern layers 18 depends to some extent on the number and the locations of the electrode pads of the bare chip because each of the interconnects 13 is separately connected to a corresponding bottom electrode 19.

Although the bottom electrodes 19 are shown as opposing the projecting electrodes 12 in FIG. 3, it is in fact a rare case that the bottom electrode 19 and the projecting electrode 12 oppose each other.

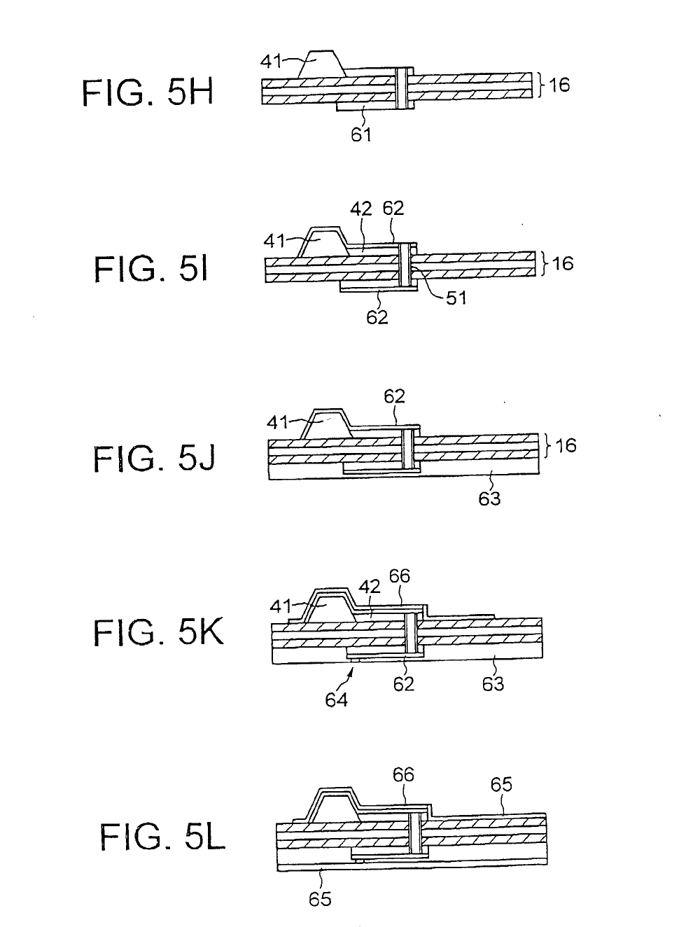

Referring to FIG. 4, the test probe 11 of the present embodiment is shown as mounted on a test board 30, with the bottom electrodes 19 mounted on the electrode pads 31 of the test board 30. The electrode pads of the device under test (DUT) not shown in the figure are generally mounted on the projecting electrodes 12 of the test probe 11. The DUT may be any type of semiconductor devices including a bare chip LSI, a packaged LSI or a plurality of bare chip LSIs layered one on another.

The sheet body 15 has a thickness as low as 100 micrometers (μm) or less, for example, and is liable to deformation by an external force to thereby absorb the warp or deformation of the test board 20 or the DUT.

The pitch of the projecting electrodes 12 may be in the range between 40 and 20 μm, with the projecting height of the projecting electrodes 12 being between 70 and 30 μm. The area for the top of the projecting electrode 12 may be around 10 μm².

The configuration as described above allows the test probe 11 to be in a suitable contact with the DUT such as a bare chip for an efficient test operation.

The multilayer wiring sheet 17 allows the test probe 11 to be adapted to any pitch of the electrodes of the test board 30. In general, the test board 30 has electrode pads arranged with a pitch which is larger than the pitch of the electrode pads of the bare chip. This configuration allows reduction of the cost for the test probe.

The electric insulation between the test board 30 and the DUT is achieved by the insulating sheet 16 to a satisfactory extent.

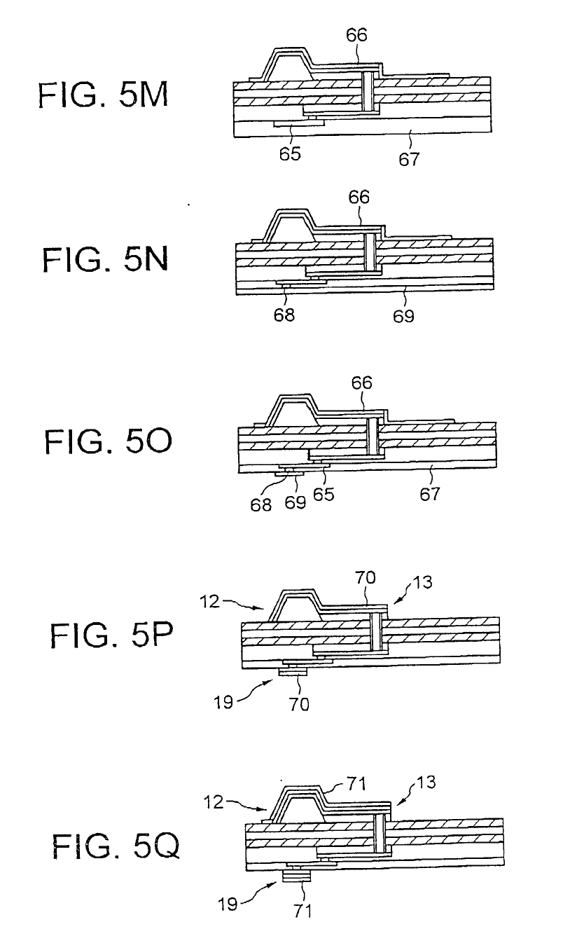

Referring to FIGS. 5A to 5Q, there is shown a fabrication process for the test probe 11 of the present embodiment. First, three silicon substrates or sheets 40, 44 and 45 are prepared, as shown in FIGS. 5A to 5C, respectively, among which the first silicon substrate 40 of FIG. 5A has a larger thickness. A silicon oxide layer 43 is formed on a side of each of the first and second silicon sheets 40 and 44, as shown in FIGS. 5A and 5B, whereas a silicon oxide layer 43 is formed on each side of the third silicon sheet 45, as shown in FIG. 5C.

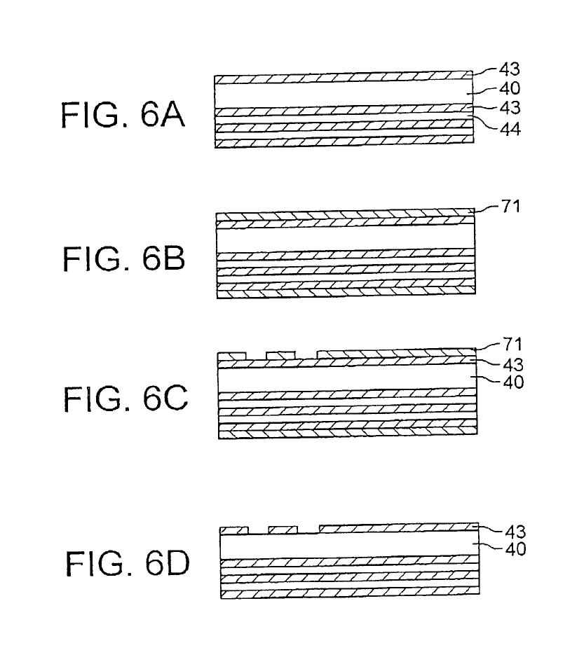

These silicon sheets are bonded together, with the thicker silicon sheet 40 being disposed at the top, to form a multilayer insulating sheet 16 wherein each silicon sheet 40, 44 or 45 is sandwiched between a pair of silicon oxide films 43, as shown in FIG. 5D. The top, thicker silicon sheet 40 is then patterned to form a silicon projection 41 and an associated planar silicon pattern (or interconnect) 42 on the silicon oxide film 43, as shown in FIG. 5E. The detail of this patterning will be described later with reference to FIGS. 6A to 6K.

A through-hole 51 is then formed penetrating the planar silicon pattern 42 and underlying silicon layers 44 and 45 by using a dry etching technique or laser beam etching technique, as shown in FIG. 5F. Then, an insulating film 52 made of SiO₂ or organic substance is formed at the inner surface of the through-hole 51.

Subsequently, the bottom silicon sheet 45 is selectively etched for patterning by a photolithographic technique to form a silicon pattern 61 on the bottom surface of the insulating sheet 16, as shown in FIG. 5H. Then, a plating process is conducted on the top and bottom surface of the insulating sheet 16 to form Cu films 62 on the silicon projection 31, the planar silicon pattern 32 and the bottom silicon pattern 61, filling the through-hole 51, as shown in FIG. 5I.

Subsequently, a photoresist film 63 is formed on the entire bottom surface of the multilayer sheet by coating and curing, as shown in FIG. 5J, followed by etching thereof to form a hole 64 reaching the Cu film 62 on the bottom silicon pattern 61, as shown in FIG. 5K. Another Cu plating is then conducted to form a Cu film 65 at the bottom and top surfaces using a mask film 66 formed on the silicon projection 41 and the planer silicon pattern 42. At this step, the hole 64 on the bottom surface is also filled with the Cu film 65. The mask 66 is left until the internal wiring layer 18 is formed.

Subsequently, a series of steps such as shown in FIGS. 5M to 5O are iterated in a desired number of times wherein the bottom Cu film 65 is patterned, followed by forming another insulating film 67 by coating, etching thereof to form a hole 68, Cu plating and patterning thereof to form an interconnect layer 69.

After a desired number of the interconnect layers 65 and 69 are formed, the mask 66 at the top surface is removed, followed by a Ni plating step to form a Ni film 70 and a Au plating step to form a Au film 71, as shown in FIGS. 5P and 5Q, on the projecting electrodes 12, interconnects 13 and the bottom electrodes 19.

Thus, a test probe of the present embodiment can be obtained.

As described before, the step for formation of the silicon projection 41 and the planar silicon pattern 42 will be described hereinafter. Referring to FIG. 6A, which is similar to FIG. 5D, as well as FIG. 6B, after the bonding of the silicon sheets is completed, a photoresist film 71 is formed by coating, as shown in FIG. 6B, followed by etching thereof for patterning.

Then, the silicon oxide film 43 is patterned using the photoresist film 71, as shown in FIG. 6C, followed by removal of the photoresist film 71, as shown in FIG. 6D. Then, the top silicon sheet 40 is subjected to a two-step wet etching process for forming the silicon projection 41 and the planar silicon pattern 42 from the silicon sheet 40.

The two-step wet etching process includes a first, anisotropic etching using an alkaline etchant and the patterned silicon oxide film 43 to form an annular trench 54, thereby isolating a portion of the silicon sheet 40 to form a silicon projection 41, as shown in FIG. 6E. The trench 54 has a surface slanted with respect to the top silicon surface by an angle of 54.74 degrees.

Examples of the etchant include a mixture of 4 mol (%) catechol, 46.4 mol (%) ethylene diamine and 49.6 mol (%) water, which is boiled at 118° C. while being blown with nitrogen and used for the etching step for a specified time length.

After the first etching, the SiO₂ films 43 are removed from the top and bottom surfaces as shown in FIG. 6F, followed by forming another SiO₂ film 56 on the top and bottom surfaces of the multilayer body, as shown in FIG. 6G. The another SiO₂ film 56 on the top surface is selectively etched to leave the same on the silicon projection 41 by using the steps of coating photoresist to form a photoresist film, patterning thereof to form a mask, patterning the SiO₂ film 56 by using the mask and removal of the mask.

The two-step wet etching process includes a second, isotropic etching to remove a top portion of the top silicon layer 40 other than the silicon projection 41, leaving a base portion 42 of the silicon layer as shown in FIG. 6I. The second etching uses an etchant such as hydrofluoric acid.

Subsequently, the base portion 42 of the silicon layer is subjected to selective etching using a photoresist film 57, as shown in FIG. 6J, whereby an interconnect pattern 42 is formed extending from the silicon projection 41, as shown in FIG. 6K.

In the first embodiment as described above, the multilayer wiring sheet 17 is formed on the bottom surface of the insulating sheet 16 by consecutively depositing layer by layer. However, the wiring sheet 17 may be formed by adhering together the insulating film 16 and the interconnect layer 17 which are separately prepared beforehand. In this case, the position aligning of the through-hole 51 with the interconnect pattern 18 in the multilayer wiring sheet 17 is especially important.

In the step of FIG. 5I, the conductive plug or via-hole 51 may be formed instead separately from the Cu plating. The plating itself is not limited to Cu plating and may be solder plating or another plating using a known material. The plating process may be also replaced by an evaporation process.

In fabrication of the test probe of FIG. 1, a process for fabricating a semiconductor device is used in the embodiment. The process is especially suited for fine patterning of the projecting electrodes 12 and the interconnects 13 corresponding to fine patterning of the electrodes of the bare chip.

In addition, the internal interconnect layers 18 can adjust the difference between the pitch of the electrodes of the DUT and the electrodes of the test board. Further, the sheet body 15 may have a smaller thickness.

The test probe should be fixed onto the test board by using a fixing member for fixing the sheet body. The DUT may be held by a suction member to be in contact with the test probe, with the projecting electrodes 12 being in electric contact with the electrodes of the DUT.

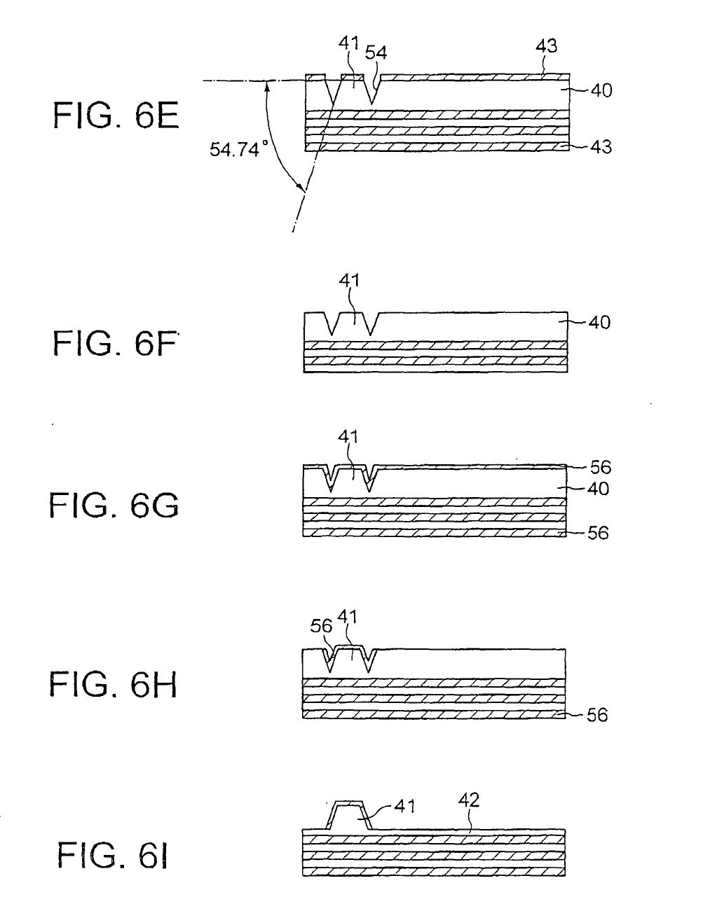

Referring to FIG. 7, a test probe 11b according to a second embodiment of the present invention has a via-hole 14b penetrating through the projecting electrode 12b to be in contact with an underlying interconnect pattern 18b in the multilayer wiring sheet 17.

In the second embodiment, the pitch of the projecting electrodes 12b may be smaller due to the absence of the planar interconnect pattern 13. In the second embodiment, however, a deep via-hole 14b should be formed as by using a laser beam etching technique.

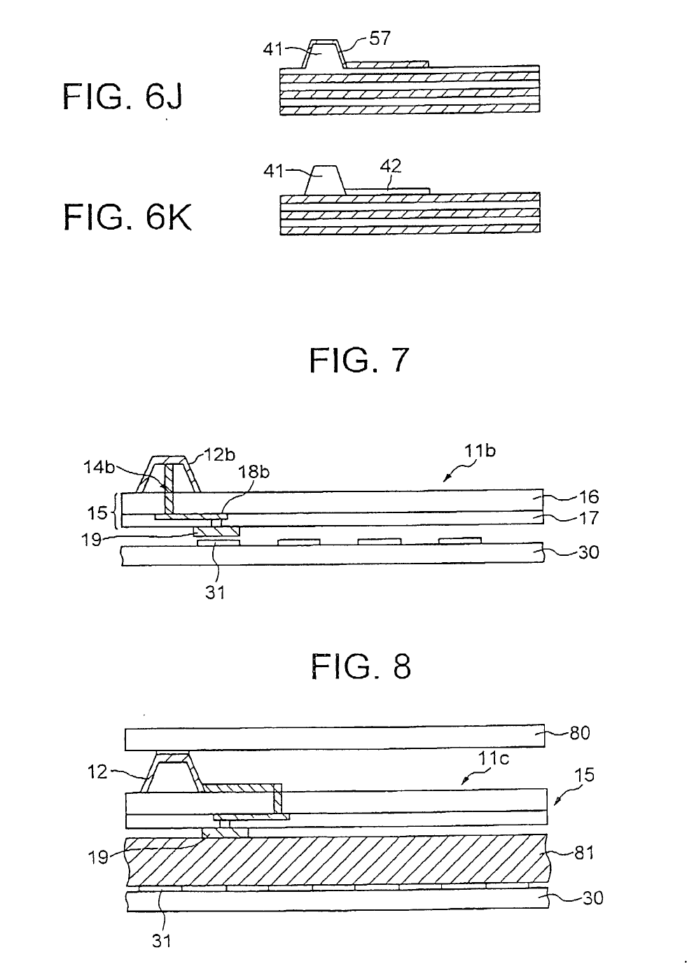

Referring to FIG. 8, a test probe 11c according to a third embodiment of the present invention is shown together with the DUT or bare chip 80 and-the test board 30. The test probe 11c of FIG. 8 is similar to the first embodiment except for an anisotropic conductive sheet 81 disposed between the sheet body 15 of the test probe 11c and the test board 30. The anisotropic conductive sheet 81 may be implemented by a metal-embedded sheet, wherein a plurality of metallic wires are uniformly embedded in a base sheet made of a silicone resin in the vertical and horizontal directions or slanted directions. The pitch of the metallic wires is smaller than the width of the bottom electrodes 19 of the test probe 11c. The top end of each metallic wire constitutes an electrode. Thus, a plurality of electrodes on the top surface of the conductive sheet 15 is in contact with the bottom electrodes 19 of the test probe 11c, although the present embodiment is not limited this configuration, and a single metallic wire may correspond to one of the bottom electrodes 19.

The anisotropic conductive sheet 81 is flexible and thus absorbs the shock applied during a test operation. The anisotropic conductive sheet 81 also adjusts the variance or errors of the dimensions or shape of the DUT and the test board. This effect is especially suitable in the case of a test probe having a relatively larger thickness which is around 100 μm and thus having a poor flexibility, or in the case of a bare chip LSI having a warp as high as several tens of micrometers.

Since the above embodiments are described only for examples, the present invention is not limited to the above embodiments and various modifications or alterations can be easily made therefrom by those skilled in the art without departing from the scope of the present invention.

What is claimed is:

1. A test probe comprising a sheet body having a top surface and a bottom surface, a plurality of first electrodes formed on said top surface, a plurality of second electrodes formed on said bottom surface and each corresponding to one of said first electrodes, and a plurality interconnects each formed inside said sheet body for connecting one of said first electrodes to a corresponding one of said second electrodes.

2. The test probe as defined in claim 1, wherein each of said first electrodes includes a projection having a height larger than a height of said second electrodes.

3. The test probe as defined in claim 2, wherein said projection includes silicon.

4. The test probe as defined in claim 1, wherein said sheet body includes an insulating sheet and a wiring sheet having at least one conductive layer implementing a part of said interconnects.

5. The test probe as defined in claim 4, wherein said insulating sheet includes a silicon oxide film.

6. The test probe as defined in claim 4, wherein said insulating sheet has a plurality of through-holes for receiving therein a part of said interconnects.

7. The test probe as defined in claim 1, wherein said first electrodes are arranged with a pitch smaller than a pitch with which said second electrodes are arranged.

8. The test probe as defined in claim 1, further comprising an anisotropic conductive sheet having a planar top surface mounting thereon a plurality of third electrodes and a planar bottom surface mounting thereon a plurality of fourth electrodes, at least one of said third electrodes corresponding to one of said second electrodes.

9. The test probe as defined in claim 8, wherein said anisotropic conductive sheet includes a resin body and a plurality of metallic wires disposed in said resin body.

10. The test probe as defined in claim 1, wherein said sheet body has a thickness equal to or below 100 micrometers.

11. A method for fabricating a test probe comprising the steps of forming a plurality of first electrodes on a top surface of an insulating sheet, forming a wiring sheet on a bottom surface of said insulating sheet, said wiring sheet having therein a plurality of interconnects each corresponding to one of said first electrodes, forming a via-hole in said insulating sheet for connecting one said first electrodes and a corresponding one of said interconnects, and forming on said wiring sheet a plurality of second electrodes each connected to a corresponding one of said interconnects.

12. The method as defined in claim 11, wherein said wiring sheet has a plurality of conductive layers implementing said interconnects.

13. The method as defined in claim 11, wherein said wiring sheet is bonded on to said bottom surface of said insulating sheet.

14. The method as defined in claim 11, wherein said first electrodes forming step includes etching a silicon film disposed on said insulating sheet.
